(19) United States
(12) Patent Application Publication
(10) Pub. No.: US 2008/0283852 A1
(43) Pub. Date: Nov. 20, 2008

(54) Light-emitting device and a method for producing the same

(76) Inventors: Yukihiro TSUJI, Yokohama-shi (JP); Kenji Hiratsuka, Yokohama-shi (JP); Mitsuo Takahashi, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/153,081

(22) Filed: May 13, 2008

(30) Foreign Application Priority Data
May 15, 2007 (JP) 2007-129788

(51) Int. Cl. H01L 33/00; H01L 21/02

(52) U.S. Cl. 257/94; 438/39; 257/E21.002; 257/E33.06; 257/E33.048

(57) ABSTRACT

A light-emitting device and a method to from the device are is described. The device described herein may realize the transversely single mode operation by the buried mesa configuration even when the active layer contains aluminum. The method provides a step to form the mesa on a semiconductor substrate with an average dislocation density of 500 to 5000 cm⁻², a step to form a protection layer, which prevents the active layer from oxidizing, at least on a side of the active layer, and a step to from a blocking layer so as to cover the protection layer and to bury the mesa.

### BACKGROUND OF THE INVENTION

1. Field of the Invention

The present invention relates to a light-emitting device and a method for manufacturing the device, in particular, the invention relates to a semiconductor laser diode with the buried mesa structure.

2. Related Prior Art

The optical communication system the uses an infrared wavelength band applies a semiconductor laser diode (hereinafter referred as LD) with the GaInAsP material system. Such an LD generally provides a buried mesa structure as the waveguide structure including an active layer to make the laser oscillation stable and in the single mode. The buried mesa structure provides a mesa including the active layer and a blocking layer with layers to form a pn-junction or with a layer showing high resistivity.

However, it is well known that the LD with the GaInAsP system shows a relatively poor temperature characteristic. That is, the LD formed from the GaInAsP system increases the threshold current and decreases the emission efficiency in high temperatures. Thus, the LD of the GaInAsP system is not a most suitable device for a light source in the optical communication system where the high-speed operation is requested with a low cost as the increase of the capacity of the information to be transmitted.

Another type of the LD has been attracted, in which the active layer includes AlGaInAs material. Because of this arrangement of the active layer, that is, aluminum is contained within the active layer; the active layer is easily oxidized during process to form the mesa when the LD has the buried mesa structure. The active layer is exposed to the air during or after etching to form the mesa. Therefore, the LD of the AlGaInAs system generally provides a ridge for the waveguide structure as disclosed in the U.S. Pat. No. 6,618,411.

The LD with the ridge waveguide structure is hard to secure the transverse single mode in the laser oscillation thereof, and the active layer in the ridge waveguide structure is easily influenced from the dislocation of the semiconductor substrate because the active layer widely spread on the substrate. This reduces the yield of the device and also deteriorates the long term reliability.

The present invention is to solve subjects above mentioned and to provide an LD made of AlGaInAs system in which the single mode operation transversely may be secured and the influence from the dislocation in the substrate may be escaped.

### SUMMARY OF THE INVENTION

One aspect of the present invention relates to a method to form a light-emitting device that includes an active layer made of AlGaInAs. The process comprises steps of: (a) forming a mesa including the active layer on a semiconductor substrate; (b) forming a protection layer at least on a side of the active layer; and (c) forming a blocking layer so as to cover the protection layer and to bury the mesa.

According to the process of the present invention, the protection layer is formed so as to cover at least the side of the active layer, which prevents the oxidization of the active layer; accordingly, even the active layer contains the aluminum, which is easily oxidized during the process, the buried mesa may be provided as the waveguide structure. Thus, the transverse single mode operation may be realized.

Moreover, the buried mesa structure may be escaped from the influence of the dislocation in the substrate compared to the ridge waveguide structure where the active layer horizontally extends along the substrate. Accordingly, the yield of the device increases and the long term reliability thereof may be enhanced.

The light-emitting device configured with the ridge waveguide structure is necessary to use the substrate with a low dislocation density because the active layer in the ridge waveguide structure horizontally and widely extends along the substrate, which means that the active layer is easily affected by the dislocation of the substrate. While, the buried mesa structure, because of its restricted area of the active layer, is unnecessary to use a substrate with the low dislocation density. Even the device uses the substrate with the dislocation density greater than 500 cm⁻², which is widely supplied in the market; the possibility that the active layer overlaps the dislocation in the substrate may be reduced. Thus, the active layer may be escaped from the influence of the dislocation in the substrate.

The process according to the present invention may include, subsequent to the formation of the mesa and prior to the formation of the protection layer, a step to etch the side of the active layer selective to the other layers sandwiching the active layer to form the hollow of the active layer, and the step to form the protection layer may be performed so as to bury this hollow of the active layer. The hollow of the active layer may facilitate the formation of the protection layer.

The substrate for the light-emitting device of the present invention preferably has a doping density of 1 to 2×10¹⁸ cm⁻³. The doping density below 2×10¹⁸ cm⁻³ may reduce the parasitic capacitance inherently caused between the substrate and the blocking layer, while, the doping density over 1×10¹⁸ cm⁻³ may reduce the dislocation density of the substrate by the impurity hardening.

Another aspect of the present invention relates to a semiconductor light-emitting device configured with a buried mesa as the waveguide structure and including an active layer containing aluminum. The light-emitting device of the present invention further provides a protection layer provided so as to cover at least a side of the active layer to protect the active layer, in particular, the aluminum contained in the active layer from oxidization. The light-emitting device further provides a blocking layer formed so as to cover the protection layer and to bury the mesa.

### BRIEF DESCRIPTION OF DRAWINGS

FIG. 1 schematically illustrates a cross section of the light-emitting device according to the first embodiment of the invention;

FIG. 2 schematically illustrates a process to form the light-emitting device shown in FIG. 1;

FIG. 3 schematically illustrates a process to form the light-emitting device subsequent to that shown in FIG. 2;

FIG. 4 schematically illustrates a process to form the light-emitting device subsequent to that shown in FIG. 3;

FIG. 5 schematically illustrates a process subsequent to that shown in FIG. 4 to form the light-emitting device shown in FIG. 1;

FIG. 6 schematically illustrates a process subsequent to that shown in FIG. 5 to form the light-emitting device according to the first embodiment shown in FIG. 1;

FIG. 7 schematically illustrates a cross section of the light-emitting device according to the second embodiment of the invention;

FIG. 8 schematically illustrates a process to form the light-emitting device according to the second embodiment of the invention that is shown in FIG. 7; and

FIG. 9 schematically illustrates a process subsequent to that shown in FIG. 8 for the light-emitting device shown in FIG. 7.

### DETAILED DESCRIPTION OF PREFERRED EMBODIMENTS

Next, preferred embodiments of the semiconductor light-emitting device and the manufacturing process thereof will be described in detail as referring to accompanying drawings. In the explanation of the drawings, the same numerals or the symbols will refer to the same elements without overlapping explanations.

### First Embodiment

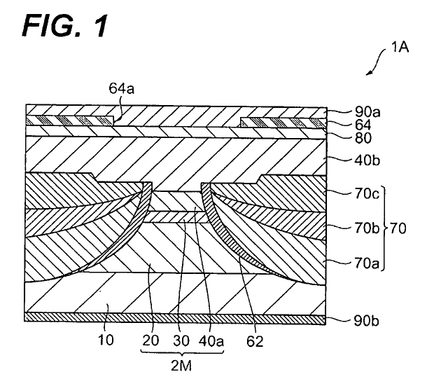

FIG. 1 schematically illustrates a cross section of a semiconductor light-emitting device 1A according to the first embodiment of the present invention. The light-emitting device 1A may be a semiconductor laser diode. As shown in FIG. 1, the light-emitting device 1A includes a semiconductor substrate 10 with the first conduction type, a mesa 2M formed on the substrate 10 and including an active layer 30, and regions provided in both sides of the mesa 2M. Each region includes a protection layer 62 and a blocking layer 70.

The substrate 10 may be an n-type InP doped with tin (Sn), which is the n-type dopant, and has conditions of an average dislocation density of 500 to 5000 cm⁻², the Sn doping density of 1 to 2×10¹⁸ cm⁻³, and a thickness of about 300 μm.

The mesa 2M includes a lower cladding layer 20 with the first conduction type, an upper cladding layer 40a with the second conduction type, and the active layer 30 put between these two cladding layers, 20 and 40a. The active layer 30 has, for instance, a multiple quantum well (MQW) structure including a plurality of well layers and a plurality of barrier layers alternately stacked to each other. The well layers and the barrier layers are made of AlGaInAs with different compositions. The lower cladding layer 20 may be an n-type InP doped with n-type impurities, typically Si, by a density of 0.5 to 1.0×10¹⁸ cm⁻³ and having a thickness of about 0.5 μm. The upper cladding layer 40a may be a p-type InP doped with p-type impurities, typically Zn, by a density of 0.3 to 0.9×10¹⁸ cm³ and having a thickness of about 0.5 μm.

The protection layer 62 fully covers the sides of the mesa 2M and may be made of InP with a thickness of about 0.1 μm. The blocking layer 70, provided in both sides of the mesa 2M, covers the protection layer 62 and buries the mesa 2M. The blocking layer 70 has a laminated structure configuration including, from a side closer to the protection layer 62, a p-type first layer 70a, an n-type second layer 70b, and a p-type third layer 70c.

The first layer 70a may be InP doped with p-type impurities such as Zn by a density of 0.5 to 1.0×10¹⁸ cm⁻³ and having a thickness of about 1.0 to 2.0 μm. The second layer 70b may be InP doped with n-type impurities such as Si by a density of 0.1 to 0.5×10¹⁸ cm⁻³ and having a thickness of about 1.0 to 2.0 μm. The third layer 70c may be InP doped with p-type impurities (Zn) by a density of 0.5 to 1.0×10¹⁸ cm⁻³ and having a thickness of about 0.1 μm.

The light-emitting device 1A further provides a second upper cladding layer 40b, a contact layer 80 and an insulating layer 64 so as to cover the mesa 2M, the protection layer 62 and the blocking layer 70. This second cladding layer 40b is provided on the first cladding layer 40a in the mesa 2M, the protection layer 62 and the p-type third layer 70c. The second upper cladding layer 40b may be InP doped with p-type impurities by a density of 1.0 to 5.0×10¹⁸ cm⁻³ and having a thickness of about 1.0 to 2.0 μm. The contact layer 80 may be InGaAs doped with p-type impurities (Zn) by a density of 1.0 to 5.0×10¹⁹ cm⁻³ and having a thickness of about 0.5 μm.

The insulating layer 64 may be made of inorganic material containing silicon, such as silicon dioxide (SiO₂) or silicon nitride (SiN), and has a thickness of about 0.1 to 0.5 μm. This insulating layer 64 forms an opening 64a whose position is aligned with the mesa 2M. An electrode, for instance, an anode electrode 90a is formed so as to cover a portion of the insulating layer 64 and the contact layer 80 exposed in the opening 64a of the insulating layer 64. On the other hand, another electrode, for instance, a cathode electrode 90b is formed in the back surface of the substrate 10.

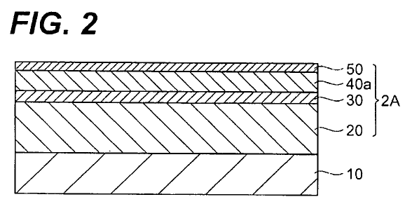

FIGS. 2 to 6 specifically illustrate processes to form the light-emitting device 1A. Next, the process will be described.

Growth of Semiconductor Layers

First, a stack 2A of semiconductor layers is grown on the substrate 10. The stack 2A includes the lower cladding layer 20, the active layer 30, the upper cladding layer 40a and a cap layer 50. The metal organic vapor phase epitaxy (OMVPE) technique may be used to grow these layers sequentially.

Formation of Mesa

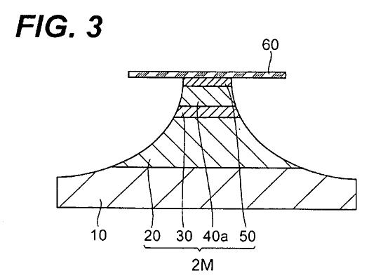

Second, the mesa 2M is formed by, what is called, the wet-etching of the layer stack 2A using a methanol bromide as an etchant (FIG. 3). Specifically, Depositing an insulating film, typically made of SiN, on the layer stack 2A, and a striped pattern 60 of the insulating film with a width of 1.0 μm and a length of about 300 μm is formed by the ordinary photolithography technique. Then, the layer stack 2A is wet-etched by this striped pattern 60 as the etching mask. The wet-etching is carried out until the substrate 10 exposes. The wet-etching removes a portion of the layer stack 2A not covered by the striped pattern 60 and forms the mesa 2M.

Formation of Protection Layer

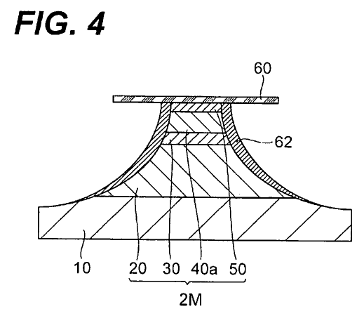

Third, the process forms the protection layer 62 on both sides of the mesa 2M (FIG. 4). In this process, the substrate 10 is set in the furnace of the OMVPE apparatus just after the formation of the mesa 2M. Then, the furnace is raised, as supplying phosphine (PH₃), to a temperature so as to cause the mass-transportation of InP from the substrate on the sides of the mesa 2M. Typical exemplary conditions of the mass-transportation are a temperature of 685° C., a processing time of 20 minutes, and an atmospheric gas of PH₃ with a flow rate of 100 sccm.

Formation of Blocking Layer

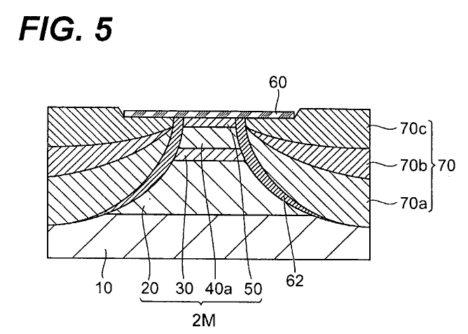

Fourth, the blocking layer 70 is formed to make a current confinement structure. As shown in FIG. 5, the blocking layer 70 is formed by the sequential growth of the first layer 70a with the p-type conduction on the sides of the protection layer 62, the n-type second layer 70b on the first layer 70a and the p-type third layer 70c on the second layer 70b. The p-type impurities may be Zn, while, the n-type impurities may be sulfur (S) or silicon (Si).

After the growth of the blocking layer 70, the striped mask 60 is removed by the wet-etching using a fluoric acid (HF), and subsequently, the cap layer 50 is also removed by the wet-etching with a mixture of phosphoric acid (H₃PO₄) and hydrogen peroxide (H₂O₂), the composition of which may be H₃PO₄:H₂O₂=5:1. Thus, the mesa 2M comprising the lower cladding layer 40a, the active layer and the upper cladding layer 20 is completed.

Formation of Upper Cladding Layer and Contact Layer

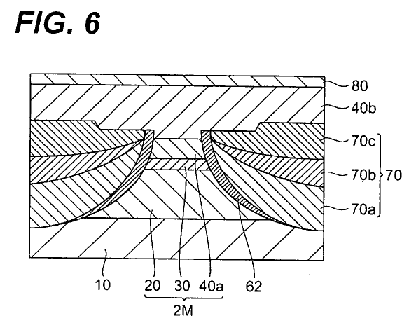

Fifth, the second upper cladding layer 40b and the contact layer 80 are formed (FIG. 6). Specifically, the second upper cladding layer 40b is grown formed on the first upper cladding layer 40a in the mesa 2M, on the protection layer 62 and on the blocking layer 70; and the contact layer 80 is grown on the second upper cladding layer 70. In these growths, the p-type impurities may be Zn.

Formation of Insulating Layer

Sixth, on the contact layer 80 is formed with the insulating layer 64 by, for example, a chemical vapor deposition technique. This insulating layer 64 may be made of silicon oxide (SiO₂) or silicon nitride (SiN). Subsequent to the deposition of the insulating layer 64, an opening 64a is formed by a combination of the ordinary photolithography technique and the etching carried out subsequent to the photolithography. The opening 64a extends along mesa 2M and has a width slightly wider than that of the mesa 2M. This insulating layer 64 may confine the current supplied to the mesa 2M.

Formation of Electrode

Seventh, on the insulating layer 64 and the contact layer 80 is formed with the electrode 90a, for instance, the anode when the contact layer 80 has the p-type conduction, while, the back surface of the substrate 10 is formed with the other electrode 90b, for instance, the cathode when the substrate 10 has the n-type conduction. Prior to the formation of the electrode 90b, it is preferable to thin the substrate 10 until a thickness of about 100 μm by grinding or polishing as the substrate 10 is attached with the supporting silica plate. The metals for the electrodes, 90a and 90b, may be deposited by the evaporation technique. Thus, the semiconductor light-emitting device 1A shown in FIG. 1 may be completed.

In the light-emitting device 1A, the protection layer 62 provided in both sides of the mesa may prevent the oxidization of the active layer, in particular, the aluminum (Al) contained in the active layer. Accordingly, a buried mesa structure may be realized even in a semiconductor laser diode with the AlGaInAs system. Conventionally, such a laser diode primarily containing AlGaInAs material in the active layer thereof is necessary to configure the ridge waveguide structure due to the oxidization of the active layer containing aluminum during the subsequent manufacturing process. The protection layer of the present invention may realize the laser diode with the buried mesa structure primarily containing AlGaInAs.

The buried mesa structure has various advantages. First, the single transverse mode in the laser oscillation is available. The ridge waveguide structure widely and horizontally extends its the active layer, which not only disperses the injected current but also the active layer becomes sensitive to the dislocations widely distributed in the substrate 10. In particular, when the semiconductor layers are epitaxially grown on the substrate, the grown layer is likely to reflect the dislocation in the substrate. Therefore, widely extended active layer is likely to be affected from the dislocation in the substrate. On the other hand, the buried mesa structure may not only confine the injected current within the mesa by the burying layer, but also the active layer may be hard to be affected by the dislocations outside of the mesa because of its narrowed area. Thus, the long term reliability of the device 1A may be enhanced.

Even when the light-emitting device according to the present invention uses the semiconductor substrate with an average dislocation density thereof over 500 cm⁻², which is easily available in the field, the active layer 30 may be escaped from the influence of the dislocation in the substrate 10. Numerically, assuming that the substrate 10 has the average dislocation density of about 500 cm⁻², the mesa 2M with a width of 1 μm and a length of 250 μm covers at least one dislocation by a possibility of merely 500×1×250×10⁻⁸=0.12%.

The present light-emitting device uses the substrate with the dislocation density below 5000 cm⁻², by which the possibility that the mesa 2M is affected by the dislocation in the substrate 10 increases to about 1%. However, such a possibility is practically acceptable and the light-emitting device may show the excellent long term reliability.

The substrate used in the present invention has a doping concentration of tin (Sn) in a range of 1 to 2×10¹⁸ cm⁻³. Generally, the dislocation density of the semiconductor substrate decreases as the impurity concentration doped therein increase by the impurity hardening effect, while, the parasitic capacitance of the device increases as the doping concentration of the substrate, which this deteriorates the high-frequency performance of the light-emitting device. Accordingly, the substrate used in the present device has a relatively low dislocation density because of relatively great Sn concentration over 1×10¹⁸ cm⁻³, while shows a small parasitic capacitance because of the impurity concentration smaller than 2×10¹⁸ cm⁻³. Such a doping concentration in the substrate 10 brings an internal resistance of the device 1A low enough.

Moreover, the device according to the present embodiment provides the protection layer 62 which is formed by the mass-transportation of InP from the substrate 10 during the heat treatment in the OMVPE reactor, where the substrate is set in just after the formation of the mesa 2M. This sequential process also enables to grow the blocking layer 70 continuously to the growth of the protection layer 62, which may simplify the process.

### Second Embodiment

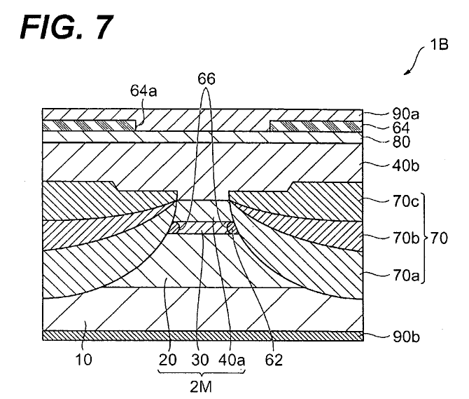

FIG. 7 schematically illustrates a cross section of the semiconductor light-emitting device 1B according to the second embodiment of the invention. The device 1B may also be an LD and, comparing with device 1A of the first embodiment, has a feature that the mesa 2M provides a hollow 66 in each side of the active layer and the protection layer 62 only covers each side of the active layer 30 so as to bury the hollow 66, while, in the light-emitting device 1A of the first embodiment, the protection layer 62 fully covers the side of the mesa 2M. Other arrangements in the device 1B are identical with those in the first device 1A of the first embodiment.

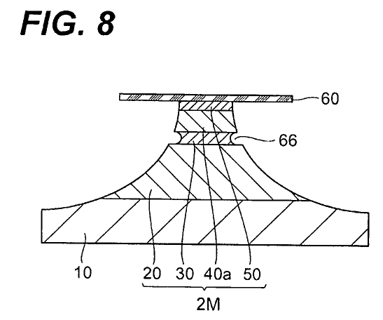

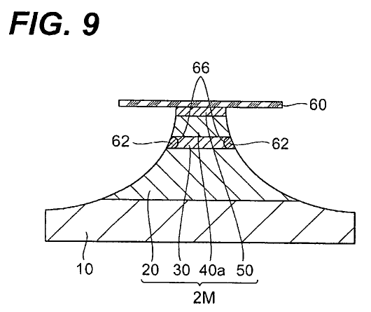

Next, processes to form the device 1B will be described as referring to FIGS. 8 and 9. FIG. 8 is a cross section to illustrate the process to form the hollow 66 in each side of the active layer 30, while, FIG. 9 is a cross section to show the process to bury the hollow 66 by the protection layer 62.

Formation of Hollow

As shown in FIG. 8, the hollow 66 is formed by the selective etching of the active layer 30 by about 0.15 μm with respect to the other layers in the mesa 2M. The selective etching may be carried out by a mixed solution of the sulfuric acid, hydrogen peroxide, and water, whose concentration is H₂SO₄:H₂O₂:H₂O=1:10:220.

Formation of Protection Layer

Next, the protection layer buries the hollow 66 by the mass-transportation of InP. Specific conditions to cause the mass transportation are same as those described in the first embodiment. These sequential processes may form the light-emitting device 1B shown in FIG. 7.

Although it is generally difficult to cause the mass-transportation in the plane side of the mesa 2M, the hollow 66 surrounding by the active layer 30 and the upper and lower cladding layers, 20 and 40a, facilitates the mass-transportation of InP. Thus, even when the active layer 30 includes aluminum, which is easily oxidized during the subsequent process, the light-emitting device 1B with the AlGaInAs material system may provide the buried mesa structure as the waveguide structure. Accordingly, the process to form the light-emitting device 1B may also show advantages described in the first embodiment.

The light-emitting devices, 1A and 1B, may be operated as follows; for instance, applying a bias voltage between the electrodes, 90a and 90b, such that the potential of the electrode 90a becomes higher, positive carriers (holes) are injected from the electrode 90a through the opening 64a in the insulating layer 64, and the carriers thus injected may be concentrated in the mesa 2M by the blocking layer 70 and effectively confined within the active layer 30. The carriers thus confined within the active layer 30 recombine with the other carriers (electrons) injected from the other electrode 90b, and generate the photons in the active layer 30.

While the invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For instance, the light-emitting devices, 1A and 1B, may be an light-emitting-diode (LED), an LD with the quantum wire structure, an LD with the quantum dot structure, an LD with the quantum box structure, or an LD with a type of the vertical cavity surface emitting laser diode with the quantum box structure in the active layer thereof. The embodiments above have the multi-quantum well structure in the active layer 30; however, the active layer may have the bulk structure or the single quantum well structure.

Moreover, although the embodiments above described have the substrate 10 doped with Sn, the dopant in the substrate may be sulfur (S) and silicon (Si). Also, the substrate 10 may have the p-type conductivity. In this case, the lower cladding layer 20 and the second layer 70b are also changed to the p-type material, while, the upper cladding layers, 40a and 40b, and the first and third layers, 70a and 70c are replaced to the n-type material. It is therefore intended that the appended claims encompass any such modifications or embodiments.

What is claimed is:

1. A method to form a semiconductor light-emitting device whose active layer is made of AlGaInAs, comprising steps of:
forming a mesa including said active layer on a semiconductor substrate;
forming a protection layer at least on a side of said active layer; and
forming a blocking layer so as to cover said protection layer and to bury said mesa.

2. The method according to claim 1,
wherein said substrate has a dislocation density greater than 500 cm⁻².

3. The method according to claim 2,
wherein said substrate has a dislocation density smaller than 5,000 cm⁻².

4. The method according to claim 1,
wherein said substrate has a doping density greater than 1×10¹⁸ cm⁻³ and smaller than 2×10¹⁸ cm⁻³.

5. The method according to claim 1,
wherein said protection layer fully covers a side of said mesa.

6. The method according to claim 1,
wherein said step to form said mesa includes, after forming said mesa, a step of etching a side of said active layer selectively so as to form a draw back of said active layer and
wherein said step to form said protection layer buries said draw back by said protection layer.

7. A semiconductor light-emitting device comprising;
a semiconductor substrate;
a mesa formed of said semiconductor substrate, said mesa including an active layer made of AlGaInAs;
a protection layer formed so as to cover at least a side of said active layer to protect aluminum contained in said active layer from oxidization;
a blocking layer formed so as to cover said protection layer and to bury said mesa.

8. The semiconductor light-emitting device according to claim 7,
wherein said semiconductor substrate has a dislocation density greater than 500 cm⁻².

9. The semiconductor light-emitting device according to claim 8,
wherein said semiconductor substrate has dislocation density smaller than 5000 cm⁻².

10. The semiconductor light-emitting device according to claim 7,
wherein said substrate has a doping density greater than 1×10¹⁸ cm⁻³ and smaller than 2×10¹⁸ cm⁻³.

11. The semiconductor light-emitting device according to claim 7,
wherein said protection layer fully covers a side of said mesa.

12. The method according to claim 7,
wherein said active layer forms a draw back and said protection layer buries said draw back.
